(19) United States
(12) Patent Application Publication
(10) Pub. No.: US 2023/0032039 A1
(43) Pub. Date: Feb. 2, 2023

(54) CHAMBER CLEANING METHOD

(71) Applicant: JUSUNG ENGINEERING CO., LTD., Gwangju-Si, Gyeonggi-Do (KR)

(72) Inventor: Won Tae CHO, Gwangju-Si, Gyeonggi-Do (KR)

(21) Appl. No.: 17/791,878

(22) PCT Filed: Jan. 8, 2021
(86) PCT No.: PCT/KR2021/000248

§ 371 Date: Jul. 8, 2022

(30) Foreign Application Priority Data
Jan. 10, 2020 (KR) 10-2020-0003827

(51) Int. Cl. H01J 37/32

(52) U.S. Cl. CPC H01J 37/32862; H01J 37/3244; H01J 2237/335

(57) ABSTRACT

The present disclosure relates to a method for cleaning a camber, and more particularly, to a method for cleaning a chamber, which is capable of cleaning a chamber contaminated in a process of depositing a thin film on a substrate. A method for cleaning a chamber, in which a thin film is deposited, in accordance with an exemplary includes primarily cleaning the chamber by using a first gas plasmalized inside the chamber and supplying a second gas plasmalized outside the chamber into the chamber to activate the plasmalized first gas, thereby secondarily cleaning the chamber. The second gas includes a gas that is non-reactive with respect to the first gas.

### TECHNICAL FIELD

The present disclosure relates to a method for cleaning a camber, and more particularly, to a method for cleaning a chamber, which is capable of cleaning a chamber contaminated in a process of depositing a thin film on a substrate.

### BACKGROUND ART

In general, semiconductor devices are manufactured by depositing various materials in the form of a thin film on a substrate to pattern the deposited thin film. For this, several stages of different processes such as a deposition process, an etching process, a cleaning process, and a drying process are performed. Here, the deposition process is performed to form a thin film having properties required as a semiconductor device on the substrate. However, during the deposition process for forming the thin film, byproducts including the deposition material is deposited not only on a desired area of the substrate but also inside the chamber in which the deposition process is performed.

If the byproducts deposited inside the chamber increase in thickness, the byproducts are peeled off to cause generation of particles. The particles generated as described above are introduced into the thin film formed on the substrate or attached to a surface of the thin film to act as a cause of defects in the semiconductor device, thereby increasing in defect rate of products. Thus, it is necessary to remove the byproducts deposited inside the chamber before the byproducts are peeled off.

In the case of metal-organic chemical vapor deposition (MOCVD), a process of cleaning the chamber is periodically performed to remove the byproducts deposited inside the chamber during the deposition process. In the case of a substrate processing apparatus that performs the MOCVD, the byproducts inside the chamber may be removed through a wet etching method using a cleaning liquid or a dry etching method using a cleaning gas. When a metal is contained in the byproducts deposited inside the chamber, the dry etching using the cleaning gas is often not easy. As a result, in the case of the substrate processing apparatus that performs the MOCVD, the inside of the chamber is mainly cleaned by the wet etching. The cleaning using the wet etching is mostly performed to allow an operator to directly manually clean the chamber in a state in which the chamber is opened. Thus, cleaning costs increase, and it is difficult to secure device reproducibility and operation rate.

### RELATED ART DOCUMENTS

(Patent document 1) KR10-2011-7011433 A

### DISCLOSURE

### Technical Problem

The present disclosure provides a method for cleaning a chamber, which is capable of efficiently cleaning a chamber in which byproducts are deposited after a thin film is deposited.

The present disclosure also provides a method for cleaning a chamber, which is capable of efficiently removing byproducts containing a metal deposited inside the chamber of a substrate processing apparatus that performs metal-organic chemical vapor deposition.

### Technical Solution

In accordance with an exemplary embodiment, a method for cleaning a chamber, in which a thin film is deposited, includes: primarily cleaning the chamber by using a first gas plasmalized inside the chamber; and supplying a second gas plasmalized outside the chamber into the chamber to activate the plasmalized first gas, thereby secondarily cleaning the chamber, wherein the second gas includes a gas that is non-reactive with respect to the first gas.

The primarily cleaning of the chamber may be performed by generating direct plasma inside the chamber, and the secondarily cleaning of the chamber may be performed by supplying remote plasma into the chamber.

The first gas may contain a chlorine component, and the second gas may include at least one of a nitrogen gas, an argon gas, a helium gas, and an oxygen gas.

A gas injection unit configured to inject the first gas may be installed in the chamber, and the primarily cleaning of the chamber and the secondarily cleaning of the chamber may be performed by controlling a temperature of the gas injection unit to a temperature of approximately 200° C. or more.

The primarily cleaning of the chamber may include: separating a first component gas and a second component gas from each other inside the chamber to supply the separated first and second component gases; plasmalizing the first component gas and the second component gas inside the chamber to react, thereby generating a plasmalized first gas; and primarily removing byproducts within the chamber by using the plasmalized first gas.

In the generating of the plasmalized first gas, the first component gas may be plasmalized outside the gas injection unit, and the second component gas may be plasmalized inside the gas injection unit.

The first component gas and the second component gas, which are plasmalized, may react with each other outside the gas injection unit.

The method may further include, after secondarily cleaning the chamber, removing the chlorine component remaining the chamber.

The thin film and the byproducts within the chamber may include metal oxide.

### Advantageous Effects

In accordance with the method for cleaning the chamber in accordance with the exemplary embodiment, the chamber may be cleaned firstly using the first gas that is plasmalized in the chamber, and then, the second gas that is plasmalized outside the chamber may be supplied into the chamber to activate the first gas that is plasmalized in the chamber, thereby cleaning the chamber secondarily. Therefore, the various byproducts remaining in the chamber may be removed step by step to maximize the cleaning efficiency. Particularly, the byproducts containing the metal deposited in the chamber of the substrate processing apparatus that performs the metal-organic vapor deposition may be efficiently cleaned.

In addition, in accordance with the method for cleaning the chamber in accordance with the exemplary embodiment, the byproducts inside the chamber may be removed without excessively increasing in temperature inside the chamber. That is, the active energy may be supplied to the first gas that is plasmalized by the plasmalized second gas to remove the byproducts while the inside of the chamber is maintained in the relatively low temperature state. Therefore, it is particularly effective in the substrate processing apparatus that is applied to the encapsulation process in which the maintenance of the low temperature is required.

In addition, in accordance with the method for cleaning the chamber in accordance with the exemplary embodiment, the in-situ cleaning may be performed without opening the chamber in the chemical vapor deposition process, in which frequent cleaning is required, to improve the work efficiency and secure high device reproducibility and operation rate.

### BRIEF DESCRIPTION OF THE DRAWINGS

FIG. 1 is a schematic view of a substrate processing apparatus in accordance with an exemplary embodiment;

FIG. 2 is a schematic view of a gas injection unit in accordance with an exemplary embodiment;

FIG. 3 is an exploded view of the gas injection unit illustrated in FIG. 2;

FIG. 4 is a view illustrating a state in which direct plasma is generated in accordance with an exemplary embodiment; and

FIG. 5 is a schematic view of a method for cleaning a chamber in accordance with an exemplary embodiment.

### DETAILED DESCRIPTION

Hereinafter, exemplary embodiments of the present inventive concept will be described in detail with reference to the accompanying drawings. The present inventive concept may, however, be embodied in different forms and should not be construed as limited to the exemplary embodiments set forth herein. Rather, these embodiments are provided so that the present inventive concept will be thorough and complete, and will fully convey the scope of the present inventive concept to those skilled in the art. In the figures, the dimensions of layers and regions may be exaggerated for clarity of illustration. Like reference numerals refer to like elements throughout.

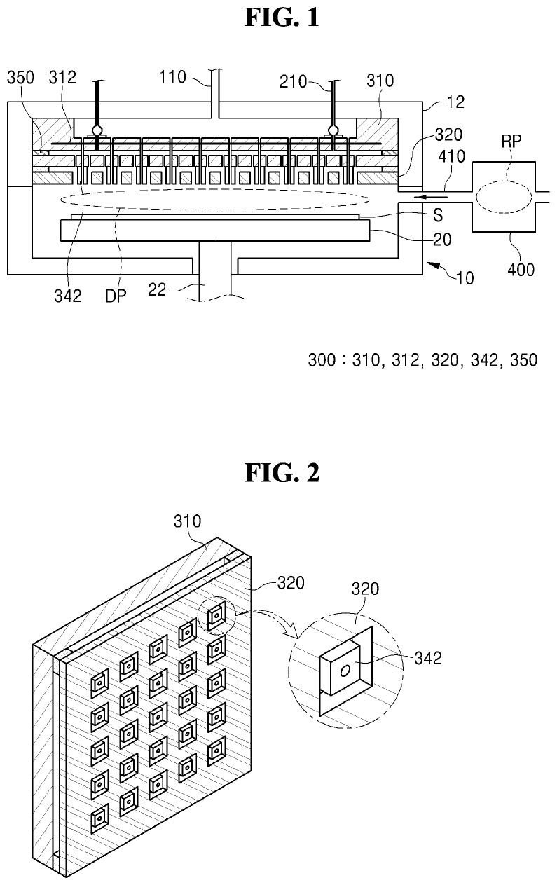

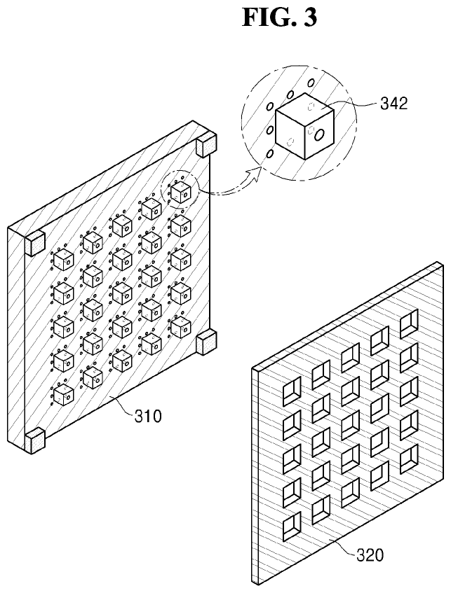

FIG. 1 is a schematic view of a substrate processing apparatus in accordance with an exemplary embodiment. Also, FIG. 2 is a schematic view of a gas injection unit in accordance with an exemplary embodiment, and FIG. 3 is an exploded view of the gas injection unit illustrated in FIG. 2.

Referring to FIGS. 1 to 3, a substrate processing apparatus in accordance with an exemplary embodiment includes a chamber 10 and a gas injection unit 300 installed in the chamber 10 to define a gas supply passage through which a gas is supplied. Also, the substrate processing apparatus may further include a power supply unit (not shown) connected to the gas injection unit 300 to apply power to the gas injection unit 300 and a plasma generation unit 400 installed outside the chamber 10. In addition, the substrate processing apparatus may further include a first gas supply unit (not shown) configured to supply a first component gas, a second gas supply unit (not shown) configured to supply a second component gas, and a control unit (not shown) configured to control the power supply unit. Here, a substrate support unit 20 configured to support at least one substrate may be installed in the chamber 10.

In the substrate processing apparatus in accordance with an exemplary embodiment, when a cleaning cycle of the chamber 10 is reached, after completing a thin film deposition process, the cleaning process may be continuously performed under a vacuum state without opening the chamber 10. A substrate S is put into the chamber 10 to deposit a thin film on the substrate S, and then, when the thin film deposition process is completed, after the thin film process is completed, the cleaning process of cleaning the inside of the chamber 10 is continuously performed. When the cleaning process is completed, another substrate S may be put into the chamber 10, and then, a thin film deposition process may be performed again. In this process, the cleaning process is performed in the chamber 10 without being changed from a pressure condition for performing the thin film deposition process to a pressure condition for opening the chamber 10.

Here, the thin film deposition process may be a process of depositing zinc oxide doped with at least one of indium (In) or gallium (Ga) on the substrate S, for example, metal oxide such as IZO, GZO, and IGZO. In this case, byproducts deposited inside the chamber 10 may include zinc oxide doped with at least one of indium (In) or gallium (Ga).

The first component gas supply unit and the second component supply unit may be installed outside the chamber to supply a first component gas and a second component gas to the gas injection unit 300, respectively. In the thin film deposition process, each of the first component gas and the second component gas may include a source gas forming a component of the thin film. In the cleaning process, each of the first component gas and the second component gas may include a cleaning gas, i.e., a cleaning gas forming the component of the first gas in a process (S100) of primarily cleaning the chamber 10, which will be described later. Here, each of the first gas supply unit and the second gas supply unit does not necessarily provide one gas. For example, each of the first gas supply unit and the second gas supply unit may supply a plurality of gases at the same time or supply a gas selected from the plurality of gases.

For example, the first gas supply unit may be configured to selectively supply a first source gas or a first cleaning gas, and the second gas supply unit may be configured to selectively supply a second source gas or a second cleaning gas. Also, the first gas supply unit may supply a plurality of first source gases at the same time or may supply a first source gas selected from the plurality of first source gases. This structure may also be equally applied to the second gas supply unit.

Here, the first source gas may be an organic source including a metal element. For example, the first source gas may be a gas including at least one or more of a gas containing indium (In) as a raw material, a gas containing gallium (Ga) as a raw material, and a gas containing zinc (Zn) as a raw material, and the second source gas may be a gas that reacts with the first source gas.

Also, the first cleaning gas may include a gas containing chlorine (Cl) component, and the second cleaning gas may contain a component different from the gas containing the chlorine (Cl) component or the first cleaning gas and include a gas containing a component that reacts with the chlorine (Cl) component of the first cleaning gas. Here, the first gas reacting with the first cleaning gas and the second cleaning gas may include Cl₂, HCl, or BCl₃.

The first source gas, the second source gas, the first cleaning gas, and the second cleaning gas may be not limited as described above, and various types of gases may be used as necessary.

The gas injection unit 300 may include a first gas supply passage 110 and a second gas supply passage 210, which are installed inside the chamber 10, for example, on a bottom surface of a chamber lid 12 to supply the first gas and the second gas, respectively. The first gas supply passage 110 and the second gas supply passage 210 may be provided to be independent and separated from each other, for example, may separate the inside of the chamber 10 so that the first gas and the second gas are not mixed with each other.

The gas injection unit 300 may include an upper frame 310 and a lower frame 320. Here, the upper frame 310 is detachably coupled to the bottom surface of the chamber lid 12, and simultaneously, a portion of a top surface of the upper frame 310, for example, a central portion of the top surface of the upper frame 310 is spaced a predetermined distance from the bottom surface of the chamber lid 12. Thus, the first gas supplied from the first gas supply unit may be diffused into a space between the top surface of the upper frame 310 and the bottom surface of the chamber lid 12. Also, the lower frame 320 is installed to be spaced a predetermined distance from the bottom surface of the upper frame 310. Thus, the second gas supplied from the second gas supply unit may be diffused into a space between the top surface of the lower frame 320 and the bottom surface of the upper frame 310. The upper frame 310 and the lower frame 320 may be connected to each other along an outer circumferential surface to define the spaced space therein and be integrated with each other and may have a structure that seals the outer circumferential surface by a separate sealing member 350.

In the first gas supply passage 110, the first gas supplied from the first gas supply unit may be diffused into the space between the bottom surface of the chamber lid 12 and the upper frame 310 to pass through the upper frame 310 and the lower frame 320 and then be supplied into the chamber 10. Also, in the second gas supply passage 210, the second gas supplied from the second gas supply unit may be diffused in the space between the bottom surface of the upper frame 310 and the top surface of the lower frame 320 to pass through the lower frame 320 and then be supplied into the chamber 10. The first gas supply passage 110 and the second gas supply passage 210 may not communicate with each other. Thus, the first gas and the second gas may be separately supplied from the gas injection unit 300 into the chamber 10.

A temperature control unit 312 may be installed in at least one of the upper frame 310 or the lower frame 320. Although the temperature control unit 312 is installed in the upper frame 310 in FIG. 1, the temperature control unit 312 may be installed in the lower frame 320 or may be installed in each of the upper frame 310 and the lower frame 320.

Here, the temperature control unit 312 may include a heating unit for directly heating the gas injection unit 300. In this case, the heating unit may be a heating unit including a resistance heating line or a heating unit that employs other heating manners. Also, the heating unit may be provided as a heating line.

Also, the heating unit may be installed in at least one of the upper frame 310 or the lower frame 320 and may be installed to be divided so as to heat a plurality of regions. Here, the heating units installed to be divided into a plurality of parts may heat at least one of the upper frame 310 or the lower frame 320 for each region. For example, the heating units may be installed in two, three, or four regions of at least one of the upper frame 310 or the lower frame 320, respectively. More heating units may be disposed closer to a chamber wall to increase in temperature of a chamber wall side having a temperature less than that a central side inside the chamber 10.

As described above, the heating unit may be installed in each of the upper frame 310 and the lower frame 320. Here, the heating unit installed in the upper frame 310 may be referred to as a first heating unit, and the heating unit installed in the lower frame 320 may be referred to as a second heating unit.

The temperature control unit 312 may include a cooling unit for directly cooling the gas injection unit 300. The cooling unit may be provided as a cooling line through which a cooling fluid is circulated. Like the heating unit, the cooling unit may be installed in at least one of the upper frame 310 or the lower frame 320 and may be installed to be divided so as to cool a plurality of regions.

RF power may be applied from the power supply unit to one of the upper frame 310 and the lower frame 320. The upper frame 310 and the lower frame 320 may be provided as electrodes facing each other. Here, the upper frame 310 may be a first electrode, and the lower frame 320 may be a second electrode 320 with respect to the first electrode 310. Also, the second electrode may have a plurality of through-portions. A plurality of protrusions 342 extending and protruding toward the plurality of through-portions of the second electrode 320 may be disposed on the first electrode 310.

FIG. 4 is a view illustrating a state in which direct plasma is generated in accordance with an exemplary embodiment. Hereinafter, although the first electrode 310 and the substrate support unit 20 are grounded, and power is applied to the second electrode 320, the structure of applying the power is not limited thereto.

As illustrated in FIG. 4, the first component gas may be supplied to the inside of the chamber along an arrow shown by a solid line, and the second component gas may be supplied to the inside of the chamber 10 along an arrow shown by a dotted line. The first component gas may be supplied to the inside of the chamber 10 by passing through the inside of the first electrode 310, and the second component gas may be supplied to the inside of the chamber 10 through a space spaced between the first electrode 310 and the second electrode 320. The first component gas may be supplied to the inside of the chamber 10 through the plurality of protrusions 342 of the first electrode 310.

When the first electrode 310 and the substrate support unit 20 are grounded, and the power is applied to the second electrode 320, a region in which first direct plasma is generated, i.e., a first direct plasma region DP1 may be defined between the gas injection unit 300 and the substrate support unit 20, and a region in which second direct plasma is generated, i.e., a second direct plasma region DP2 may be defined between the first electrode 310 and the second electrode 320.

Thus, when the first component gas is supplied by passing through the first electrode 310, the first component gas may be plasmalized in the first direct plasma region DP1 defined outside the gas injection unit 300. Also, when the second component gas is supplied through the space spaced between the first electrode 310 and the second electrode 320, the second component gas may be plasmalized between the first electrode 310 and the second electrode 320, which correspond to the inside of the gas injection unit 300, i.e., over a region from the second direct plasma region DP2 to the first plasma region DP1. Thus, in the substrate processing apparatus in accordance with an exemplary embodiment, the first component gas and the second component gas may be plasmalized in the plasma regions having volumes different from each other. Also, since the first component gas and the second component gas are plasmalized in the plasma regions having the volumes different from each other, the component gases may be distributed into optimal supply passages for depositing the thin film or cleaning the chamber 10. Although a substrate S is seated on the substrate support unit 20 in FIGS. 1 and 4, this may be applied when the thin film is deposited on the substrate S. When the chamber 10 is cleaned, the substrate S may be carried out and may not be disposed on the substrate support unit 20.

The substrate processing apparatus in accordance with an exemplary embodiment may further include a remote plasma generation unit 400 installed outside the chamber 10. The remote plasma generation unit 400 may be installed outside the chamber 10 and connected to the chamber 10 through a remote plasma inflow tube 410. A region in which remote plasma is generated, i.e., a remote plasma region RP may be defined in the remote plasma generation unit 400. Here, one end of the remote plasma inflow tube 410 may communicate with the remote plasma region RP, and the other end of the remote plasma inflow tube 410 may communicate with an inner space of the chamber 10. Here, the other end of the remote plasma inflow tube 410 may extend to be inserted into the inner space of the chamber 10. The other end of the remote plasma inflow tube 410, which is inserted into the inner space of the chamber 10, may be installed to be reciprocated along an extension direction of the chamber 10. Although the remote plasma generation unit 400 is installed to be spaced apart from the chamber in a lateral direction of the chamber 10, the remote plasma generation unit 400 may be installed to be spaced from the chamber 10 in a longitudinal direction or lateral and longitudinal directions of the chamber 10.

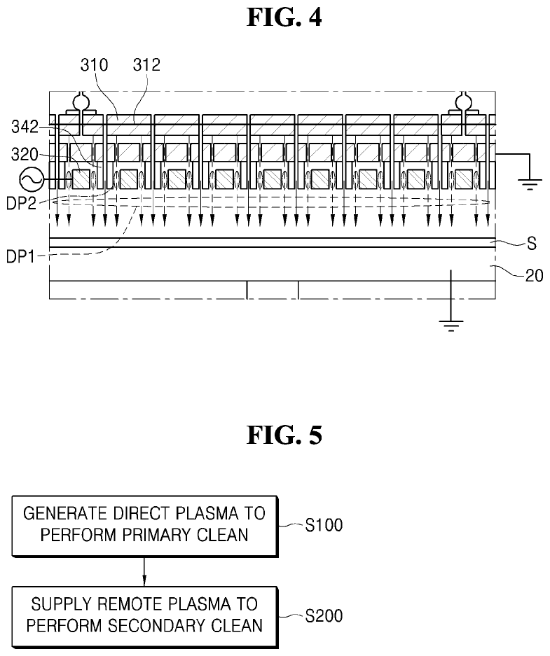

Hereinafter, a method for cleaning the chamber in accordance with an exemplary embodiment will be described in detail with reference to FIG. 5. In description of the method for cleaning the chamber in accordance with an exemplary embodiment, description duplicated with the descriptions of the above-described substrate processing apparatus will be omitted.

FIG. 5 is a schematic view of a method for cleaning a chamber in accordance with an exemplary embodiment. Referring to FIG. 5, a method for cleaning a chamber in accordance with an exemplary embodiment is a method for cleaning the chamber configured to deposit the thin film as described above and includes a process (S100) of primarily cleaning a chamber 10 by using a first gas that is plasmalized inside the chamber 10 and a process (S200) of supplying a second gas, which is plasmalized outside the chamber 10, into the chamber 10 to secondarily clean the chamber 10. Here, the second gas may include a gas that is a non-reactive with respect to the first gas.

For convenience of explanation, hereinafter, although the gas injection unit 300 has a structure including the upper frame 310 and the lower frame 320, which are described above, the gas injection unit 300 may be a gas injection plate, a shower head, a gas injection plate which has an electrode for forming plasma, or lid itself.

A process of depositing a thin film on a substrate S may be performed after the process (S100) of primarily cleaning the chamber 10. In the process of depositing the thin film on the substrate S, a thin film including metal oxide may be deposited on the substrate S. That is, in the process of depositing the thin film on the substrate S, zinc oxide doped with at least one of indium (In) or gallium (Ga), for example, metal oxide such as IZO, GZO, and IGZO may be deposited on the substrate S. Thus, in the chamber 10, the metal oxide such as zinc oxide doped with at least one of indium (In) or gallium (Ga) may be deposited as by-products.

After the process of depositing the thin film on the substrate S, before the process (S100) of primarily cleaning the chamber 10, a process of controlling a temperature of the gas injection unit 300 to a set temperature may be performed. Here, in the process of controlling the temperature of the gas injection unit 300 to the set temperature, the temperature of the gas injection unit 300 may be controlled to a temperature of approximately 200° C. or more. That is, after the process of depositing the thin film on the substrate S, the process (S100) of primarily cleaning the chamber 10 may be performed in a continuous in-situ manner while maintaining a vacuum state without opening the chamber 10. A process of controlling the temperature of the gas injection unit 300 to the set temperature may be performed between the process of depositing the thin film and the process (S100) of primarily cleaning the chamber 10. This is because of maximizing cleaning efficiency when the gas injection unit 300 has a high temperature. As described above, since the temperature of the gas injection unit 300 increases, the byproducts within the chamber 10 and the first gas may more actively react with each other.

Here, the process of controlling the temperature of the gas injection unit 300 to the set temperature may include a process of directly heating the gas injection unit 300. That is, as described above, a heating unit may be installed in at least one of an upper frame 310 and a lower frame 320, which are provided in the gas injection unit 300. In the process of controlling the temperature of the gas injection unit 300 to the set temperature, at least one of the upper frame 310 or the lower frame 320 may be directly heated by the heating unit to control the temperature of the gas injection unit 300 to a temperature of approximately 200° C. or more. Here, the process of directly heating the gas injection unit 300 may be performed simultaneously with heating the substrate support unit 20 for supporting the substrate S. As described above, when the heating unit directly heats the gas injection unit 300 together with heating the substrate support unit 20, the temperature of the gas injection unit 300 may be quickly controlled to the set temperature.

In the process (S100) of primarily cleaning the chamber 10, a component, which reacts at a relatively low temperature, among the metal oxide deposited as the byproducts inside the chamber may react with the first gas to primarily clean the chamber 10.

Here, the process (S100) of primarily cleaning the chamber 10 may be performed by generating direct plasma inside the chamber 10. Also, the process (S100) of primarily cleaning the chamber 10 may include a process of separating a first component gas and a second component gas from each other inside the chamber 10 to supply the separated first and second component gases, a process of plasmalizing the first component gas and the second component gas inside the chamber 10 to react, thereby generating a plasmalized first gas, and a process of primarily removing the byproducts within the chamber 10 by using the plasmalized first gas.

In the process (S100) of primarily cleaning the chamber 10, to clean the chamber 10 in which the byproducts containing the metal oxide are deposited, the first component gas and the second component gas may be plasmalized in different regions to react, thereby generating the plasmalized first gas, thereby removing the byproducts inside the chamber 10. That is, in the method for cleaning the chamber in accordance with an exemplary embodiment, since the first component gas and the second component gas are plasmalized in the different regions, the chamber 10 in which the byproducts containing the metal oxide are deposited may be cleaned in a dry manner.

In the process of separating the first component gas and the second component gas from each other to supply the first component gas and the second component gas into the chamber, the first component gas supplied from a first gas supply unit and the second component gas supplied from a second gas supply unit may be supplied into the chamber 10 through the gas injection unit 300. That is, the first component gas and the second component gas may be supplied into the chamber 10 along a first gas supply passage 110 and a second gas supply passage 210, which are provided as passages different from each other within the gas injection unit 300.

The first component gas and the second component gas may react with each other in an inner space of the chamber 10 to generate a reaction gas. At least one of the first component gas or the second component gas may be a gas containing a chlorine (Cl) component. Here, the gas containing the chlorine (Cl) component may include Cl₂, HCl, or BCl₃. Also, the first component gas or the second component gas may further include at least one inert gas such as argon (Ar), xenon (Ze), and helium (He) in addition to the chlorine (Cl)-containing gas. In this case, the inert gas may serve as a carrier gas or prevent the first component gas or the second component gas from flowing backward. When power is applied, discharge efficiency for generating the direct plasma may be improved.

The first component gas and the second component gas may be supplied into the chamber 10 along the separate passages inside the gas injection unit 300, respectively. That is, the first component gas may be supplied into the chamber 10 along the first gas supply passage 110 formed in the gas injection unit 300, and the second component gas may be supplied into the chamber 10 along the second gas supply passage 210 that is formed in the gas injection unit 300 and does not communicate with the first gas supply passage 110. As described above, the first component gas and the second component gas may be respectively supplied into the chamber 10 along the separate passages within the gas injection unit 300 to prevent the first component gas and the second component gas from reacting with each other inside the gas injection unit 300, thereby preventing the gas injection unit 300 from being damaged and more effectively cleaning the inside of the chamber 10.

In the process of generating the plasmalized first gas, the first component gas and the second component gas may be plasmalized in the direct plasma region formed in the chamber 10, and the first and second component gases, which are plasmalized in the direct plasma region, may react with each other in the reaction space within the chamber 10 to generate the plasmalized first gas.

Here, as described with reference to FIG. 4, in the process of generating the plasmalized first gas, when the first component gas is supplied to pass through the first electrode 310, the first component gas is plasmalized in a first direct plasma region DP1. Also, when the second component gas is supplied through a space spaced between the first electrode 310 and the second electrode 320, the second component gas is plasmalized from a second direct plasma region DP2 and then plasmalized over the first direct plasma region DP1. Therefore, in the process of generating the plasmalized first gas, the first component gas and the second component gas may be plasmalized in the direct plasma regions having different volumes. When the first component gas and the second component gas are plasmalized in the direct plasma regions having different volumes, the region in which the direct plasma is generated may be expanded up to a region between the first electrode 310 and the second electrode 320 to improve plasma density within the chamber 10 and also distribute the first component gas and the second component gas to the optimal supply passage for generating the plasmalized first gas.

Also, the plasmalized first and second component gases may be supplied into the chamber 10 through the separate passages so as to be partially used as a cleaning gas for directly cleaning the chamber 10. However, for example, when the chlorine (Cl)-contained gas is used as the first component gas, and the hydrogen (H)-contained gas is used as the second component gas, a hydrogen chloride (HCl) gas, in which the first component gas and the second component gas react with each other, may be used as the cleaning gas. In this case, since the plasmalized chlorine (Cl)-contained gas and the plasmalized hydrogen (H)-contained gas have high mutual reactivity, the first gas for etching the byproducts within the chamber 10, for example, the hydrogen chloride (HCl) gas may be generated. Here, the generated hydrogen chloride (HCl) gas may be used as a main reaction gas for efficiently removing the byproducts containing organic metal oxide such as zinc oxide deposited inside the chamber 10.

In the process of removing the byproducts within the chamber by using the plasmalized first gas, the plasmalized first gas may physically and chemically react with the byproducts within the chamber 10 to etch and remove the byproducts. For example, the chlorine (Cl) component contained in the first gas may physically and chemically react with the byproducts deposited inside the chamber 10 to efficiently etch the byproducts containing the organic metal oxide such as zinc oxide generated in metal-organic chemical vapor deposition (MOCVD), thereby primarily removing the byproducts.

The process (S200) of secondarily cleaning the chamber 10 may be performed by supplying remote plasma into the chamber 10. In the process (S200) of secondarily cleaning the chamber 10, the second gas supplied into the chamber 10 may activate the first gas plasmalized inside the chamber 10 in the above-described process (S100) of primarily cleaning the chamber 10, and then the first gas plasmalized by the second gas and the component, which reacts at a relatively high temperature, among the metal oxide deposited as the byproducts within the chamber 10 may react with each other to secondarily clean the chamber 10.

In more detail, in the step (S100) of primarily cleaning the chamber 10, the first gas may be plasmalized by the direct plasma to primarily remove the byproducts which are deposited inside the chamber 10 and contains the component that react at a relatively low temperature. However, as described above, the byproducts may include the metal oxide and contain the component, which reacts at the relatively high-temperature, among the metal oxide and thus may contain byproducts that are not removed by the first gas plasmalized as described above. Here, in the process (S100) of primarily cleaning the chamber 10, when the second gas that is plasmalized outside the chamber 10 is supplied into the chamber 10, the first gas may be activated by the supplied plasmalized second gas. That is, the second gas may be plasmalized by the high-temperature remote plasma and then be supplied into the chamber 10. As described above, the second gas plasmalized outside the chamber 10 and then supplied into the chamber 10 may supply activation energy such as light energy, heat energy, kinetic energy, and the like to the first gas that is plasmalized inside the chamber 10, and the first gas may be excited and activated to a higher energy state by the activation energy supplied from the second gas as well as the direct plasma within the chamber 10. Here, the second gas may include a gas that is non-reactive with respect to the first gas. As described above, the second gas may include at least one gas of a nitrogen (N₂) gas, an argon (Ar) gas, a helium (He) gas, and oxygen (O₂), which do not react with the chlorine (Cl) component contained in the first gas. Here, the non-reactive with respect to the first gas may not mean that the gas does not completely react with the first gas, but mean a case in which almost no reaction occurs because an amount of reacting gas is remarkable small even when only a portion of the gas reacts. As a result, in the process (S100) of primarily cleaning the chamber 10, the byproducts may be primarily removed by the plasmalized first gas, which is generated inside the chamber 10 by the direct plasma. After the byproducts are primarily removed, since most of the high-density byproducts are chlorinated to be removed, the byproducts containing the component that reacts at the relatively high temperature may be removed by the plasma of the first gas that is additionally activated. Here, the process (S100) of primarily cleaning the chamber 10 and the process (S200) of secondarily cleaning the chamber 10 may be performed in a state in which the temperature of the gas injection unit 300 is maintained to the set temperature, for example, approximately 200° C. or more. As described above, the first gas may receive the activation energy by heating the gas injection unit 300.

The method for cleaning the chamber in accordance with an exemplary embodiment may further include a process of removing the chlorine (Cl) component remaining in the chamber 10 after the process (S200) of secondarily cleaning the chamber 10. As described above, the process of removing the chlorine (Cl) component remaining in the chamber 10 may be performed by supplying a third gas, which reacts with the chlorine (Cl) component, for example a hydrogen (H₂)-contained gas, into the chamber 10. In addition, the third gas may be plasmalized outside the chamber 10 and then supplied into the chamber 10. As described above, hydrogen (H) radicals generated by the hydrogen plasma treatment may react with the chlorine (Cl) component, and thus, residue of the chlorine (Cl) component remaining in the chamber 10 may be removed.

As described above, the hydrogen (H) radicals generated by the hydrogen plasma treatment may react with the chlorine (Cl) component, and thus, the residue of the chlorine (Cl) component remaining in the chamber 10 may be removed. Also, after the hydrogen plasma treatment, the residue of the hydrogen (H) component may remain in the chamber 10. Therefore, a fourth gas, for example, an oxygen (O₂)-contained gas may be supplied into the chamber 10 to remove the residue of the hydrogen (H) component. Here, the fourth gas may be plasmalized outside the chamber 10 and then supplied into the chamber 10. As described above, oxygen (O₂) radicals generated by the oxygen plasma treatment may react with the hydrogen (H) component, and thus, residue of the hydrogen (H) component remaining in the chamber 10 may be removed.

In accordance with the method for cleaning the chamber in accordance with the exemplary embodiment, the chamber may be cleaned firstly using the first gas that is plasmalized in the chamber, and then, the second gas that is plasmalized outside the chamber may be supplied into the chamber to activate the first gas that is plasmalized in the chamber, thereby cleaning the chamber secondarily. Therefore, the various byproducts remaining in the chamber may be removed step by step to maximize the cleaning efficiency. Particularly, the byproducts containing the metal deposited in the chamber of the substrate processing apparatus that performs the metal-organic vapor deposition may be efficiently cleaned.

In addition, in accordance with the method for cleaning the chamber in accordance with the exemplary embodiment, the byproducts inside the chamber may be removed without excessively increasing in temperature inside the chamber. That is, the active energy may be supplied to the first gas that is plasmalized by the plasmalized second gas to remove the byproducts while the inside of the chamber is maintained in the relatively low temperature state. Therefore, it is particularly effective in the substrate processing apparatus that is applied to the encapsulation process in which the maintenance of the low temperature is required.

In addition, in accordance with the method for cleaning the chamber in accordance with the exemplary embodiment, the in-situ cleaning may be performed without opening the chamber in the chemical vapor deposition process, in which frequent cleaning is required, to improve the work efficiency and secure high device reproducibility and operation rate.

Although the specific embodiments are described and illustrated by using specific terms, the terms are merely examples for clearly explaining the exemplary embodiments, and thus, it is obvious to those skilled in the art that the exemplary embodiments and technical terms can be carried out in other specific forms and changes without changing the technical idea or essential features. Therefore, it should be understood that simple modifications according to the exemplary embodiments of the present inventive concept may belong to the technical spirit of the present inventive concept.

What is claimed is:

1. A method for cleaning a chamber, in which a thin film is deposited, the method comprising:
primarily cleaning the chamber by using a first gas plasmalized inside the chamber; and
supplying a second gas plasmalized outside the chamber into the chamber to activate the plasmalized first gas, thereby secondarily cleaning the chamber,
wherein the second gas comprises a gas that is non-reactive with respect to the first gas.

2. The method of claim 1, wherein the primarily cleaning of the chamber is performed by generating direct plasma inside the chamber, and
the secondarily cleaning of the chamber is performed by supplying remote plasma into the chamber.

3. The method of claim 1, wherein the first gas contains a chlorine component, and
the second gas comprises at least one of a nitrogen gas, an argon gas, a helium gas, and an oxygen gas.

4. The method of claim 1, wherein a gas injection unit configured to inject the first gas is installed in the chamber, and
the primarily cleaning of the chamber and the secondarily cleaning of the chamber are performed by controlling a temperature of the gas injection unit to a temperature of 200° C. or more.

5. The method of claim 4, wherein the primarily cleaning of the chamber comprises:
separating a first component gas and a second component gas from each other inside the chamber to supply the separated first and second component gases;
plasmalizing the first component gas and the second component gas inside the chamber to react, thereby generating the plasmalized first gas; and
primarily removing byproducts within the chamber by using the plasmalized first gas.

6. The method of claim 5, wherein, in the generating of the plasmalized first gas, the first component gas is plasmalized outside the gas injection unit, and the second component gas is plasmalized inside the gas injection unit.

7. The method of claim 6, wherein the first component gas and the second component gas, which are plasmalized, react with each other outside the gas injection unit.

8. The method of claim 3, further comprising, after secondarily cleaning the chamber, removing the chlorine component remaining the chamber.

9. The method of claim 1, wherein the thin film and byproducts within the chamber comprise metal oxide.
